(19) United States
(12) Patent Application Publication
(10) Pub. No.: US 2024/0288681 A1
(43) Pub. Date: Aug. 29, 2024

(54) MEMS OPTICAL DEFLECTOR AND OPTICAL SCANNING DEVICE

(71) Applicant: STANLEY ELECTRIC CO., LTD., Meguro-ku, Tokyo (JP)

(72) Inventor: Susumu NAKAMURA, Tokyo (JP)

(73) Assignee: STANLEY ELECTRIC CO., LTD., Meguro-ku, Tokyo (JP)

(21) Appl. No.: 18/576,974

(22) PCT Filed: Jun. 20, 2022
(86) PCT No.: PCT/JP2022/024558

§ 371 Date: Jan. 5, 2024

(30) Foreign Application Priority Data
Jul. 13, 2021 (JP) 2021-115431

(51) Int. Cl. G02B 26/08; B81B 3/00; G02B 26/10

(52) U.S. Cl. CPC G02B 26/0858; B81B 3/0045; G02B 26/10; B81B 2201/042; B81B 2203/0154; B81B 2207/03

(57) ABSTRACT

An optical scanning device includes a mirror portion, a torsion bar extending along a resonance axis, an annular-shaped body coupled to the torsion bar from both sides of the resonance axis to rotate the mirror portion, and an intersection portion piezoelectric element and/or coupling portion piezoelectric elements formed in a rigidity adjustment region including an intersection portion of the torsion bar and the annular-shaped body to change a rigidity of the rigidity adjustment region when a voltage is applied.

### TECHNICAL FIELD

The present invention relates to a MEMS optical deflector and an optical scanning device including a MEMS optical deflector.

### BACKGROUND ART

A MEMS optical deflector is known in which a mirror portion is supported by a pair of torsion bars extending along a rotation axis, the torsion bars are twisted and vibrated around the rotation axis, and the mirror portion is reciprocated around the rotation axis at a resonance frequency (example: Patent Literatures 1 and 2).

In the MEMS optical deflector, the resonance frequency generally varies within a certain range including a design value due to manufacturing variation or the like.

In the MEMS optical deflector of Patent Literature 1, a piezoelectric film is formed in the torsion bar in the entire extending direction thereof, and the torsion bar is expanded and contracted in the extending direction by applying a voltage to the piezoelectric film to change a rigidity of the torsion bar, and the resonance frequency of the mirror portion is adjusted.

In the MEMS optical deflector of Patent Literature 2, each of the torsion bars is provided with a piezoelectric element at a center position in a longitudinal direction thereof, and a voltage is applied to the piezoelectric element, so that the torsional rigidity of the torsion bar is changed and the resonance frequency of the mirror portion is adjusted.

### CITATION LIST

### Patent Literatures

Patent Literature 1: Japanese Patent Application Laid-Open No. 2008-70863
Patent Literature 2: Japanese Patent Application Laid-Open No. 2008-116668

### SUMMARY OF INVENTION

### Technical Problem

Since the torsion bar is thin and reciprocates at a high frequency, in the MEMS optical deflector of Patent Literatures 1 and 2 in which a long piezoelectric film or wiring is formed on the torsion bar, it is easy to cause a problem that the piezoelectric film is peeled off, or the wiring is broken or peeled off, or the like. Further, in the torsion bar, when the piezoelectric element is provided at an intermediate point between a support point and the mirror portion, and a voltage is applied to the piezoelectric element, stress concentration easily occurs at the intermediate point thereof, and a durability of the torsion bar is lowered.

An object of the present invention is to provide a MEMS optical deflector and an optical scanning device capable of smoothly adjusting a resonance frequency of a mirror portion around a rotation axis without causing a problem in the durability of a torsion bar.

### Solution to Problem

A MEMS optical deflector of the present invention includes
a mirror portion configured to reflect a light beam,
a one-side torsion bar and the other-side torsion bar extending from one end portion and the other end portion of the mirror portion along a rotation axis of the mirror portion, respectively,
a one-side support and the other-side support configured to intersect the one-side torsion bar and the other-side torsion bar in a one-side intersection portion and the other-side intersection portion in a vertical direction with respect to the rotation axis, respectively, and rotatably support the one-side torsion bar and the other-side torsion bar around the rotation axis in the one-side intersection portion and the other-side intersection portion, respectively,
actuators configured to rotate the one-side torsion bar and the other-side torsion bar around the rotation axis in the one-side intersection portion and the other-side intersection portion, respectively, and
a rigidity changing piezoelectric element formed in at least one setting region of a one-side setting region and the other-side setting region including at least a part of the one-side intersection portion and the other-side intersection portion in the vertical direction in the one-side torsion bar and the other-side torsion bar in a center range, respectively to change a rigidity of the one setting region when a voltage is applied.

An optical scanning device of the present invention includes
the MEMS optical deflector,
a frequency detector configured to detect a reciprocating rotation frequency of the mirror portion around the rotation axis, and
a control unit configured to control the applied voltage of the rigidity changing piezoelectric element based on an output of the frequency detector.

### Effect of the Invention

According to the present invention, it is possible to adjust the resonance frequency of the mirror portion around the rotation axis by changing the rigidity of the support portion of the torsion bar by controlling the application of the voltage of the rigidity changing piezoelectric element of the setting region. Since the setting region where the rigidity changing piezoelectric element is formed exists in the support where appropriate dimensions are ensured, the rigidity changing piezoelectric element can be generated without causing a problem in the durability of the torsion bar.

### BRIEF DESCRIPTION OF DRAWINGS

FIG. 1 is an overall schematic view of an optical scanning device.

FIG. 2 is a schematic front view of a MEMS optical deflector.

FIG. 3 is a detailed view of a range from a center of a mirror portion to a movable frame in the MEMS optical deflector of FIG. 2.

FIG. 4A is an enlarged view of a range of 4A of FIG. 3.

FIG. 4B is an enlarged view of a range of 4B of FIG. 3.

FIG. 5 is a perspective view of a rigidity adjustment region.

FIG. 6A is an explanatory view when a voltage is applied to an intersection portion piezoelectric element.

FIG. 6B is an explanatory view when a voltage is applied to a coupling portion piezoelectric element.

FIG. 6C is an explanatory view when a voltage is applied to the intersection portion piezoelectric element and the coupling portion piezoelectric element.

FIG. 7 is a graph illustrating a relationship between a voltage application state of the intersection portion piezoelectric element and the coupling portion piezoelectric element, and a resonance frequency of a mirror portion around a resonance axis using a Young's modulus E of a substrate portion in the rigidity adjustment region as a parameter.

FIG. 8 is a configuration diagram of a control device of FIG. 1.

### DESCRIPTION OF EMBODIMENTS

Hereinafter, embodiments of the present invention will be described. Needless to say, the present invention is not limited to the embodiments. Regarding common components, the same reference numerals are used throughout all the drawings.

### (Optical Scanning Device)

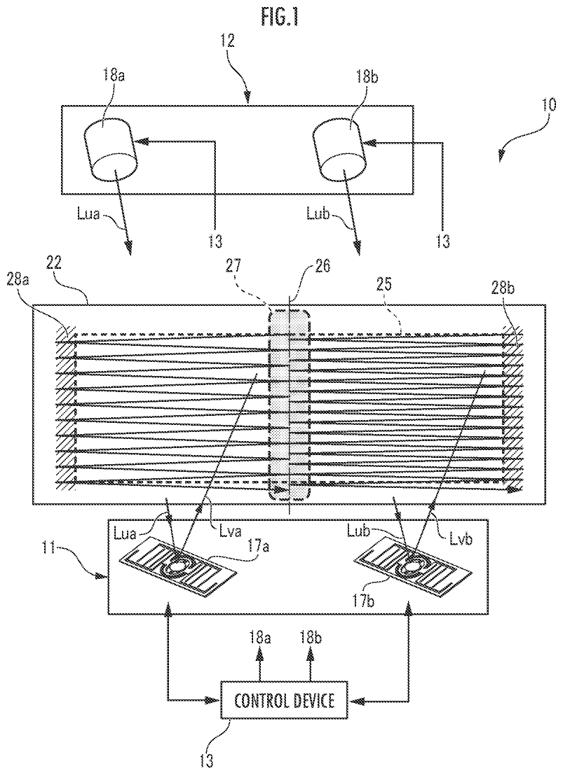

FIG. 1 is an overall schematic view of an optical scanning device 10. The optical scanning device 10 includes a MEMS device 11, a light source device 12, and a control device 13. The MEMS device 11 includes two MEMS optical deflectors 17a and 17b. The light source device 12 has two laser light sources 18a and 18b. The control device 13 controls the MEMS device 11 and the light source device 12.

A virtual screen 22 is defined for convenience in describing an operation of the optical scanning device 10. A light beam that is emitted from the optical scanning device 10 scans the virtual screen 22 and generates an image surface 25 on the virtual screen 22. The virtual screen 22 is disposed perpendicular to the light beam directed from the optical scanning device 10 to a center of the image surface 25. Vertical and horizontal of the image surface 25 are parallel to a scanning directions of the vertical and horizontal of the light beam emitted from the optical scanning device 10.

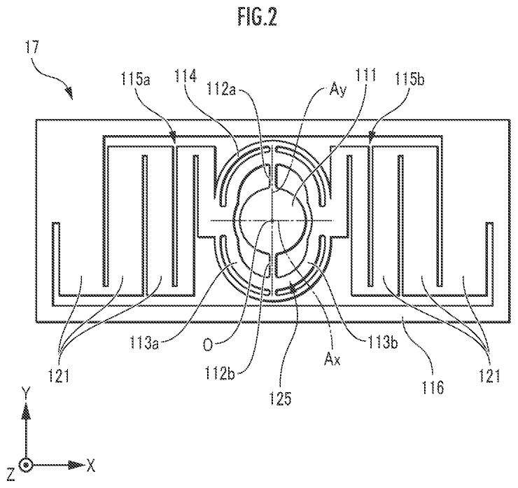

Light beams Lua and Lub from the laser light sources 18a and 18b are incident on centers of mirror portions 111 (FIG. 2) of the MEMS optical deflectors 17a and 17b, and reflected by the mirror portions 111 to become light beams Lva and Lvb, thereby being emitted from the MEMS device 11.

The light beams Lva and Lvb respective scan a left side and a right side of the image surface 25 of the virtual screen 22 with respect to a center line 26 of the image surface 25. The light beams Lva and Lvb scan between an upper side and a lower side of the image surface 25 in a vertical direction on the virtual screen 22.

When the laser light source 18a is always lit, the light beam Lva scans a range between a left end of an end range 28a and the center line 26 in a horizontal direction. When the laser light source 18b is always lit, the light beam Lvb scans a range between the center line 26 and a right end of an end range 28b in the horizontal direction. However, the end range 28a and the end range 28b are excluded from the image surface 25 as a scanning range outside the image surface 25. Typically, the control device 13 turns off the laser light sources 18a and 18b during a period when the light beams Lva and Lvb irradiate the end ranges 28a and 28b.

On the image surface 25 of FIG. 1, the number of scanning lines of the light beam Lva in the horizontal direction is less than the number of scanning lines of the light beam Lvb in the horizontal direction. The numbers means that the resonance frequency of the mirror portion 111 around a resonance axis Ay (FIG. 2) in the MEMS optical deflector 17a is lower than the resonance frequency of the mirror portion 111 around a resonance axis Ay (FIG. 2) in the MEMS optical deflector 17b. Originally, although the resonance frequency of any MEMS optical deflector 17 (general term for the MEMS optical deflectors 17a and 17b) has to be a predetermined setting value, such a difference occurs due to manufacturing variations.

When the MEMS optical deflector 17 independently generates the image of the image surface 25, even if the resonance frequency slightly deviates from the setting value, the image can be corrected by image processing of the control device 13, and thus the deterioration of the image quality can be suppressed. However, as illustrated in FIG. 1, the two MEMS optical deflectors 17 (general term for the MEMS optical deflectors 17a and 17b) are adjacent to each other in the center line 26 as a boundary line in the scanning direction (horizontal direction in FIG. 1) in the resonance direction, and the entire image is generated by being joined together, a difference in a scanning linear density in the center range 27 near the boundary line such as the center line 26 is conspicuous, and thus a user perceives the difference as a seam of the images. In order to avoid the problem, it is necessary to make adjustments so that the resonance frequencies among a plurality of MEMS optical deflectors 17 are equal.

In addition, in addition to the manufacturing variations, a temperature rise of the optical deflector itself due to an external environment such as temperature may cause the resonance frequency to exceed an allowable range in the specifications, and in that case, even an image produced by the single MEMS optical deflector 17 is not suitable for use.

### (MEMS Optical Deflector)

FIG. 2 is a schematic front view of the MEMS optical deflector 17. For convenience of the description of a configuration of the MEMS optical deflector 17, a three-axis coordinate system of an X-axis, a Y-axis, and a Z-axis that are orthogonal to each other is defined. An origin of the three-axis coordinate system is placed at a center O of the mirror portion 111. The X-axis and the Y-axis are aligned parallel to the horizontal and vertical directions of the MEMS optical deflector 17 which is rectangular when viewed in a front view. In addition, the Z-axis is aligned parallel to a direction of a plate thickness of the MEMS optical deflector 17 (thickness direction of SOI as a substrate).

The MEMS optical deflector 17 has a horizontally long rectangular shape when viewed in a front view; and is manufactured from an SOI (Silicon On Insulator) wafer. The MEMS optical deflector 17 includes torsion bars 112 (general term for upper and lower torsion bars 112a and 112b), inner actuators 113 (general term for left and right inner actuators 113a and 113b), a movable frame 114, outer actuators 115 (general term for left and right outer actuators 115a and 115b), and a fixed frame 116 in order from the mirror portion 111 of the center toward the outside.

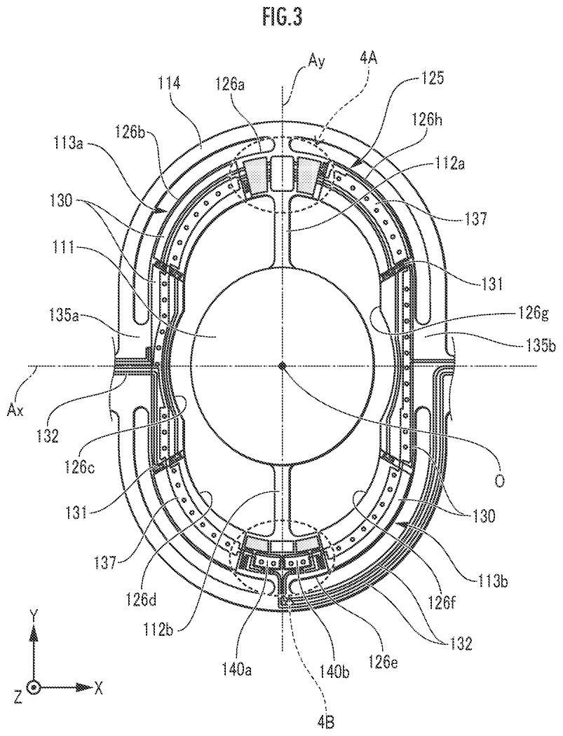

The light beams Lu (general term for the light beams Lua and Lub) from the laser light source 18 are incident on the circular mirror portion 111a at the center O. The inner actuators 113a and 113b are coupled to the torsion bar 112 from both sides to form an annular-shaped body 125 (FIG. 3) that surrounds the mirror portion 111 from the outside. The movable frame 114 forms another annular-shaped body that surrounds the annular-shaped body 125 from the outside. The torsion bars 112a and 112b extend from one end portion and the other end portion of the mirror portion 111 along the resonance axis Ay of the mirror portion 111, respectively, are coupled to the inner actuators 113a and 113b from both sides in a vertical direction to the resonance axis Ay at an intermediate portion, and are coupled to an inner periphery of the movable frame 114 at a tip thereof.

Each outer actuator 115 is formed with a plurality of cantilevers 121 in a meander array, and is interposed between the movable frame 114 and the fixed frame 116. Both the inner actuator 113 and the outer actuator 115 are piezoelectric actuators.

The mirror portion 111a reciprocally rotates in two axial directions of the resonance axis Ay and a non-resonance axis Ax, which are perpendicular to each other. The resonance axis Ay coincides with the center line of the torsion bar 112. When the mirror portion 111 faces the front, that is, when a normal line standing on the center O of the mirror portion 111 is parallel to the Z-axis, the resonance axis Ay and the non-resonance axis Ax overlap the Y-axis and the X-axis, respectively.

The reciprocating rotation of the mirror portion 111 around the resonance axis Ay utilizes the resonance of the mirror portion 111. In contrast, the reciprocating rotation of the mirror portion 111 around the non-resonance axis Ax is non-resonance. A reciprocating rotation frequency of the mirror portion 111 around the resonance axis Ay, that is, the resonance frequency is sufficiently higher than a non-resonance frequency of the mirror portion 111 around the non-resonance axis Ax.

### (Main Portion of MEMS Optical Deflector)

FIG. 3 is a detailed view of a range from the center O of the mirror portion 111 to the movable frame 114 in the MEMS optical deflector 17 of FIG. 2. As described above, the left and right inner actuators 113a and 113b are coupled to each other at both ends thereof, and form the annular-shaped body 125 as a whole.

The annular-shaped body 125 intersects the mirror portion 111 at the intermediate portion of the mirror portion 111. The annular-shaped body 125 has eight compartment regions of compartment regions 126a, 126b, 126c, 126d, 126e, 126f, 126g, and 126h counterclockwise in order from the intersection portion of the torsion bar 112a and the inner actuator 113a when viewed in a front view of the MEMS optical deflector 17.

The compartment regions 126a and 126e include the intersection portions of the torsion bar 112 and the annular-shaped body 125, and straddle both of the inner actuators 113a and 113b. The compartment regions 126b to 126d belong to the inner actuator 113a, and the compartment regions 126f to 126h belong to the inner actuator 113b.

The compartment regions 126a and 126e are compartment regions where a rigidity changing piezoelectric element is formed. The compartment regions 126b to 126d and the compartment regions 126f to 126h are compartment regions where an actuator piezoelectric element 130 is formed. In the compartment region where the actuator piezoelectric element 130 is formed, portions adjacent to each other in a circumferential direction of the annular-shaped body 125 are separated by a slit 131.

All piezoelectric elements formed on the surface of the substrate include the actuator piezoelectric elements 130 and have a three-layer structure of an upper electrode layer, a piezoelectric film layer, and a lower electrode layer, in order from top to bottom. The slit 131 cuts at least the upper electrode layer and the piezoelectric film layer of the actuator piezoelectric element 130 in the adjacent compartment region.

The wiring 132 extends along the annular-shaped body 125 and is connected to the corresponding actuator piezoelectric element 130. Drive cycle voltages having opposite phases to each other are applied to the actuator piezoelectric elements 130 in the compartment regions 126b, 126d, and 126g, and the actuator piezoelectric elements 130 in the compartment regions 126c, 126f, and 126h, and thereby the torsion bar 112 is twisted in the same rotation direction around the resonance axis Ay by the inner actuators 113a and 113b on both sides in each reciprocating rotation cycle, and reciprocally rotates around the resonance axis Ay.

Coupling portions 135a and 135b in the X-axis direction extend a range on the non-resonance axis Ax between the end of the outer actuator 115 on a movable frame 114 side and the annular-shaped body 125, and support the movable frame 114 and the annular-shaped body 125 to an end of the outer actuator 115 on the movable frame 114 side. The movable frame 114 reciprocally rotates integrally with the end of the outer actuator 115 on the movable frame 114 side around the non-resonance axis Ax during the operation of the MEMS optical deflector 17. The outer actuator 115 is coupled to the fixed frame 116 at an end opposite to the movable frame 114. As a result, the torsion bar 112 is supported by the fixed frame 116 via the annular-shaped body 125 at the intermediate portion in the longitudinal direction thereof, and is supported by the fixed frame 116 via the movable frame 114 at the end on the opposite side of the mirror portion 111 in the longitudinal direction.

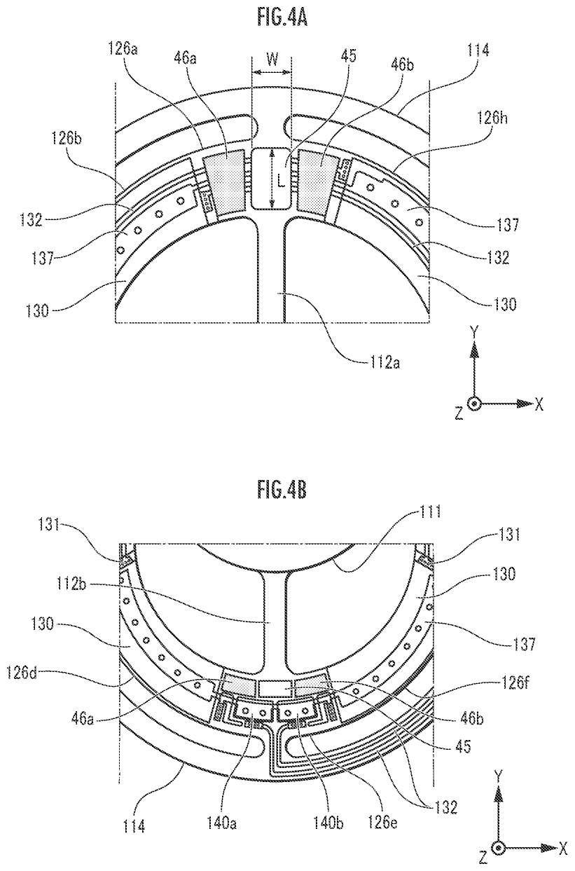

FIGS. 4A and 4B are enlarged views of ranges of 4A and 4B of FIG. 3, respectively. The ranges of 4A and 4B of FIG. 3 include the compartment regions 126a and 126e of the annular-shaped body 125 on the inside, respectively.

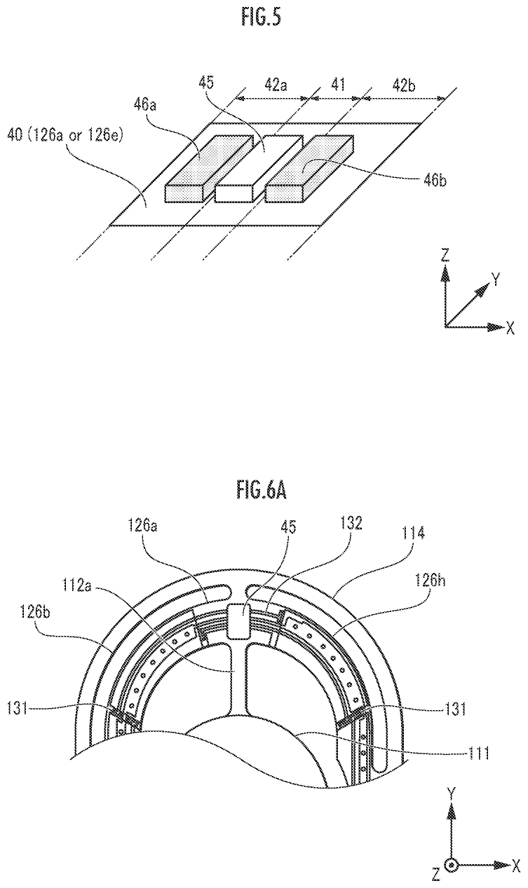

FIG. 5 is a perspective view of a rigidity adjustment region 40. The entire compartment region 126a is the rigidity adjustment region 40. In the compartment region 126e, only a half portion on the mirror portion 111 side in the direction of the resonance axis Ay is the rigidity adjustment region 40.

In the compartment region 126e, deflection angle sensors 140a and 140b are formed in the half portion of the compartment region 126e on the movable frame 114 side in the direction of the resonance axis Ay (FIG. 4B). The deflection angle sensors 140a and 140b are piezoelectric elements, and output voltages according to a torsion angle of the torsion bar 112b around the resonance axis Ay during operation of the MEMS optical deflector 17 and thus a rotation angle (deflection angle) of the mirror portion 111 around the resonance axis Ay.

The rigidity adjustment region 40 (FIG. 5) includes a center range region 41 that occupies a center range and end range regions 42a and 42b that occupy both end ranges on both sides thereof in the X-axis direction. The center range region 41 belongs to both the torsion bar 112 and the annular-shaped body 125 as the intersection portion of the torsion bar 112 and the annular-shaped body 125. The end range regions 42a and 42b belong only to the annular-shaped body 125.

The compartment region 126a of the annular-shaped body 125 intersects the torsion bar 112a in the center range region 41 in a vertical direction to the resonance axis Ay, and rotatably supports the torsion bar 112a around the resonance axis Ay in the center range region 41 as the intersection portion. As a result, the annular-shaped body 125 forms a one-side support that supports the torsion bar 112a. The compartment region 126e of the annular-shaped body 125 intersects the torsion bar 112b in the center range region 41 in the vertical direction to the resonance axis Ay, and rotatably supports the torsion bar 112b around the resonance axis Ay in the center range region 41 as the intersection portion. As a result, the annular-shaped body 125 forms the other-side support that supports the torsion bar 112b.

In FIG. 4A, W and L illustrate dimensions of the intersection portion piezoelectric element 45 in the X-axis and Y-axis directions, respectively. Since the L of the intersection portion piezoelectric element 45 is a dimension in a width direction of the annular-shaped body 125, it is possible to secure a dimension larger than the W of the intersection portion piezoelectric element 45.

As a voltage is applied to the intersection portion piezoelectric element 45, the W decreases while the L is maintained at an equal value. A decrease in the W means an increase in the rigidity of a portion where the intersection portion piezoelectric element 45 is formed (including an Si layer on the lower side) in the rigidity adjustment region 40.

Similarly, as the voltage of the coupling portion piezoelectric elements 46a and 46b is applied, the widths (dimensions in the X-axis direction) of the coupling portion piezoelectric elements 46a and 46b decrease. The decrease in the widths of the coupling portion piezoelectric elements 46a and 46b means an increase in the rigidity of the portion (including the Si layer on the lower side) where the coupling portion piezoelectric elements 46a and 46b are formed in the rigidity adjustment region 40.

### (Operation of Main Portion)

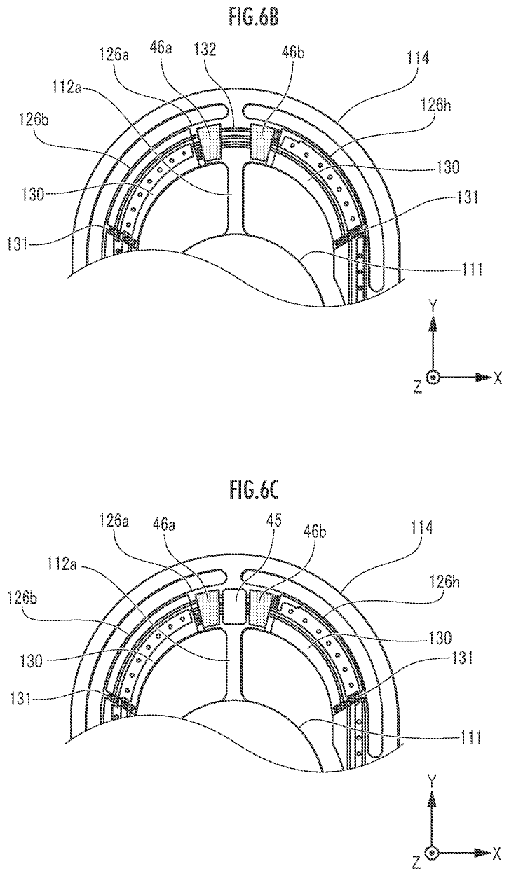

FIG. 6A is an explanatory view when a voltage is applied to the intersection portion piezoelectric element 45. As the voltage is applied to the intersection portion piezoelectric element 45 (specifically, the voltage is applied to the piezoelectric film layer of the intersection portion piezoelectric element 45 from the upper electrode and the lower electrode), the rigidity in the vicinity of the center range region 41 (including the Si layer) where the intersection portion piezoelectric element 45 is formed in the rigidity adjustment region 40 increases. As a result, the rigidity of the center range region 41 as the intersection portion in the torsion bar 112, and the resonance frequency of the mirror portion 111 around the resonance axis Ay increase.

FIG. 6B is an explanatory view when a voltage is applied to the coupling portion piezoelectric elements 46a and 46b. As the voltage is applied to the coupling portion piezoelectric elements 46a and 46b, the rigidity in the vicinity of the end range regions 42a and 42b (including the Si layer) where the coupling portion piezoelectric elements 46a and 46b are formed in the rigidity adjustment region 40 increases. In other words, the rigidity in the vicinity of the coupling portions of the inner actuators 113a and 113b that are coupled to the center range region 41 of the torsion bar 112 from both sides in the vertical direction with respect to the resonance axis Ay to support the center range region 41 increases. As a result, the rigidity of the center range region 41 is also increased by being affected by the influences of the inner actuators 113a and 113b, and as a result, the rigidity of the substrate (Si layer) itself of the torsion bars 112a and 112b is slightly improved, and thus, the resonance frequency of the mirror portion 111 around the resonance axis Ay increases.

FIG. 6C is an explanatory view when a voltage is applied to the intersection portion piezoelectric element 45 and the coupling portion piezoelectric elements 46a and 46b. In this case, the rigidity of the substrate (Si layer) in the center range region 41 where the intersection portion piezoelectric element 45 and the coupling portion piezoelectric elements 46a and 46b are formed in the rigidity adjustment region 40 increases. As a result, the uniformity in the vicinity of the center range region 41 and the end range regions 42a and 42b is enhanced, and the resonance frequency of the mirror portion 111 around the resonance axis Ay increases.

### (Simulation)

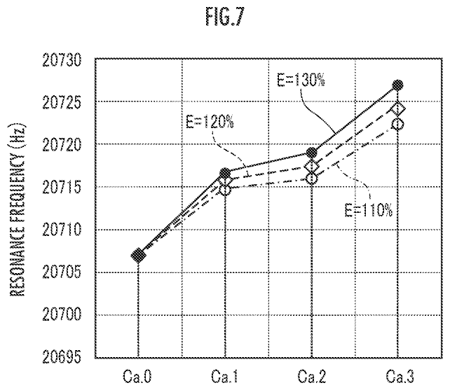

FIG. 7 is a graph illustrating a relationship between a voltage application state of the intersection portion piezoelectric element 45 and the coupling portion piezoelectric elements 46a and 46b, and the resonance frequency of the mirror portion 111 around the resonance axis Ay using a Young's modulus E of the substrate portion in the rigidity adjustment region 40 as a parameter. Characteristic values of the graph are calculated by using simulation software “IntelliSuite (registered trademark)” of Advanced Technology Co., Ltd.

In addition, a numerical value of each portion is as follows.
Diameter of the mirror portion 111: 1500 μm
Width of the torsion bar 112: 120 μm
Length of the torsion bar 112 (dimension between the mirror portion 111 and movable frame 114): 600 μm
Total area of the end range regions 42a and 42b: 50,000 square μm×2
Area of the center range region 41: 37,000 square μm

Ca.0 to Ca.3 means as follows.
Ca.0: When all of the intersection portion piezoelectric element 45 and the coupling portion piezoelectric elements 46a and 46b are set to no applied voltage
Ca.1: When a voltage is applied only to the intersection portion piezoelectric element 45 (FIG. 6A)
Ca.2: When a voltage is applied to the coupling portion piezoelectric elements 46a and 46b (FIG. 6B)
Ca.3: When a voltage is applied to all of the intersection portion piezoelectric element 45 and the coupling portion piezoelectric elements 46a and 46b (FIG. 6C)

Further, the Young's modulus E of the substrate portion of the rigidity adjustment region 40 (Si layer of the device layer of the SOI is the substrate portion) was increased by 10% with respect to 100% of a reference, and the resonance frequency was examined at 110%, 120%, and 130%.

From FIG. 7, it can be seen that the resonance frequency increases in the order of Ca.0, Ca.1, Ca.2, and Ca.3. In addition, it can be seen that the higher the Young's modulus E of the substrate, the higher the resonance frequency is.

### (Control Device)

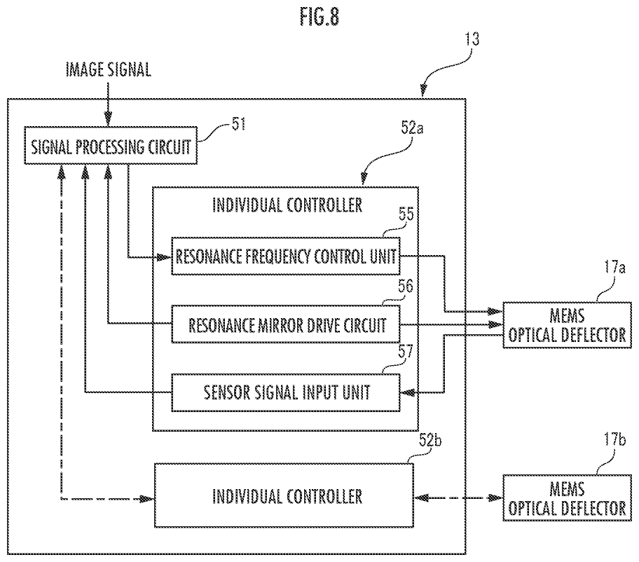

FIG. 8 is a configuration diagram of the control device 13 of FIG. 1. The control device 13 includes one signal processing circuit 51 and individual controllers 52a and 52b that are assigned to the MEMS optical deflectors 17a and 17b, respectively. The signal processing circuit 51 receives an image signal from an image source such as streaming or a storage device, and divides the image signal into a signal portion of the image portion generated by the light beam Lva of the MEMS optical deflector 17a and a signal portion of the image portion generated by the light beam Lvb of the MEMS optical deflector 17b to distribute the signal portions to the individual controllers 52a and 52b, respectively.

The individual controllers 52a and 52b have the same configuration. The individual controller 52 (general term for the individual controllers 52a and 52b) includes a resonance frequency control unit 55, a resonance mirror drive circuit 56, and a sensor signal input unit 57.

The sensor signal input unit 57 receives an output voltage of the deflection angle sensor 140 of the MEMS optical deflector 17 and outputs the output voltage to the signal processing circuit 51. The signal processing circuit 51 detects a rotation frequency around the resonance axis Ay in each MEMS optical deflector 17 based on an input from the sensor signal input unit 57 of each individual controller 52.

For this detection, for example, means is used in which driving is performed by changing a frequency in a state where the maximum voltage value of the drive waveform is constant, and a frequency having the largest deflection angle is determined as the rotation frequency, or the like. In addition, driving may be performed by changing the frequency in a state where the maximum voltage value of the drive waveform is constant, and a frequency larger than a predetermined deflection angle may be determined as a usable range as the rotation frequency. Such detection is performed, for example, at each timing when the MEMS optical deflector 17 is switched from OFF to ON.

The signal processing circuit 51 outputs the control signal to the resonance frequency control unit 55 and the resonance mirror drive circuit 56 of the individual controller 52 corresponding to the lower MEMS optical deflector 17, so that an indication rotation frequency Fi of the MEMS optical deflector 17 of the lower Fcl becomes equal to a detection rotation frequency Fch of the MEMS optical deflector 17 of the higher Fch (Fch>Fcl) in the detection rotation frequencies Fc around the resonance axis Ay in the MEMS optical deflectors 17a and 17b.

The control signal received from the signal processing circuit 51 by the resonance frequency control unit 55 is a signal related to the rigidity of the rigidity adjustment region 40. The control signal received from the signal processing circuit 51 by the resonance mirror drive circuit 56 is a signal related to the indication rotation frequency Fi (=Fch) of the mirror portion 111 around the resonance axis Ay in the MEMS optical deflector 17.

Each resonance mirror drive circuit 56 supplies a drive voltage having the indication rotation frequency Fi to the inner actuator 113 of the corresponding MEMS optical deflector 17. Further, the resonance frequency control unit 55, which receives the control signal of the rigidity change from the signal processing circuit 51, supplies a voltage that increases the rigidity of the rigidity adjustment region 40 of the corresponding MEMS optical deflector 17 to the intersection portion piezoelectric element 45 and/or the coupling portion piezoelectric element 46 of the rigidity adjustment region 40.

The signal processing circuit 51 uses, as a feedback signal, the output of the deflection angle sensor 140 in the MEMS optical deflector 17 in which is the voltage for changing the rigidity is output from the resonance frequency control unit 55, and performs feedback control to change the control signal to the resonance frequency control unit 55 until the rotation frequency around the resonance axis Ay in the MEMS optical deflector 17 becomes Fi (=Fch) based on the feedback signal.

In this manner, the rotation frequency around the resonance axis Ay in the MEMS optical deflectors 17a and 17b is aligned with Fch. The alignment means that a linear density of the light beam Lva of the MEMS optical deflector 17a in the vertical direction and a linear density of the light beam Lva of the MEMS optical deflector 17b in the vertical direction on the image surface 25 of FIG. 1 are aligned to a side with higher linear density. As a result, conspicuousness of the seam at the center line 26 of the image surface 25 is suppressed, and the image quality of the image surface 25 is improved.

### Modified Examples

In the MEMS optical deflector 17, the inner actuator 113 has an annular-shaped body. In the present invention, the actuator that rotates the torsion bar around the rotation axis at the intersection portion may be a linear piezoelectric actuator. For example, each torsion bar is coupled to the linear piezoelectric actuator from both sides in a vertical direction with respect to the rotation axis at the intermediate portion in the longitudinal direction, and reciprocally rotates around the resonance axis Ay by the linear piezoelectric actuators on both sides.

In the MEMS optical deflector 17, the actuator is the piezoelectric type actuator. The actuator of the present invention may be an electrostatic type (example: Patent Literature 1) or an electromagnetic type.

In the MEMS optical deflector 17, the movable frame 114 is provided in addition to the inner actuator 113, and the inner actuator 113 is coupled to the intermediate portion in the longitudinal direction of the torsion bar 112. In the present invention, the movable frame 114 may be omitted, and the inner actuator 113 may be coupled to the end of the torsion bar 112 on the opposite side of the mirror portion 111.

In the MEMS optical deflector 17, the rigidity adjustment region 40 is provided with a total of three rigidity changing piezoelectric elements of the intersection portion piezoelectric element 45 and the coupling portion piezoelectric elements 46a and 46b. In the present invention, it is also possible to form a rigidity changing piezoelectric element in which the intersection portion piezoelectric element 45 and the coupling portion piezoelectric elements 46a and 46b are combined into one, and one of the intersection portion piezoelectric element 45 and the coupling portion piezoelectric elements 46a and 46b may be omitted.

In the MEMS optical deflector 17, in the compartment region 126e, the rigidity adjustment region 40 as the setting region where the rigidity changing piezoelectric element is formed and the setting region where the deflection angle sensor 140 is formed are on the mirror portion 111 side and the movable frame 114 side, respectively. In the present invention, the side of the rigidity adjustment region 40 and the side of the region where the deflection angle sensor 140 is formed may be reversed.

The MEMS optical deflector 17 is a two-axis type MEMS optical deflector that reciprocally rotates the mirror portion 111 around two rotation axes of the resonance axis Ay and the non-resonance axis Ax. The MEMS optical deflector of the present invention may be a one-axis type MEMS optical deflector having only one rotation axis of the mirror portion 111.

In the optical scanning device 10, the resonance frequency of the mirror portion 111 around the resonance axis Ay in the MEMS optical deflectors 17a and 17b was adjusted to the detection rotation frequency Fch that is higher side in the detection rotation frequency before the rigidity change of the rigidity adjustment region 40. In the optical scanning device of the present invention, the resonance frequency of the mirror portion 111 around the resonance axis Ay in the MEMS optical deflectors 17a and 17b can match the rotation frequency Fcs (Fcs>Fch) that is higher than the detection rotation frequency Fch in which the detection rotation frequency is high before rigidity change of the rigidity adjustment region 40. In that case, before the rigidity change of the rigidity adjustment region 40, the MEMS optical deflector 17 having the detection rotation frequency on the high side also applies a voltage to the intersection portion piezoelectric element 45 and/or the coupling portion piezoelectric elements 46a and 46b in the rigidity adjustment region 40 to increase the rigidity of the rigidity adjustment region 40.

In the MEMS optical deflector 17, the intersection portion piezoelectric element 45 and/or the coupling portion piezoelectric elements 46a and 46b were operated in two ways of when no voltage was applied and when a voltage was applied. In the present invention, when a voltage is applied to the intersection portion piezoelectric element 45 and/or the coupling portion piezoelectric elements 46a and 46b, the applied voltage is changed in a plurality of steps or continuously, so that the rigidity of the rigidity adjustment region 40 can be changed in a plurality of steps or continuously.

In the MEMS optical deflector 17, the one-side torsion bar and the other-side torsion bar are described as the torsion bars 112a and 112b, respectively. In the present invention, the one-side torsion bar and the other-side torsion bar may be reversed.

In the MEMS optical deflector 17, the one-side intersection portion and the other-side intersection portion are described as the center range region 41 of the compartment regions 126a and 126e, respectively. In the MEMS optical deflector of the present invention, the one-side intersection portion and the other-side intersection portion may be reversed.

In the MEMS optical deflector 17, the one-side support and the other-side support are described as a half portion on the torsion bar 112a side and a half portion on the torsion bar 112b side of the annular-shaped body 125, respectively. The one-side support and the other-side support of the present invention may be reversed.

In the MEMS device 11, the MEMS optical deflectors 17a and 17b are respectively described as the first optical deflector and the second optical deflector. In the present invention, the MEMS optical deflectors 17a and 17b may be the second optical deflector and the first optical deflector, respectively.

### DESCRIPTION OF REFERENCE NUMERALS

10 . . . optical scanning device
17a, 17b . . . MEMS optical deflector
18 . . . laser light source
40 . . . rigidity adjustment region
41 . . . center range region
42 . . . end range region
45 . . . intersection portion piezoelectric element
46 . . . coupling portion piezoelectric element
111 . . . mirror portion
112a. 112b . . . torsion bar
113 . . . inner actuator
114 . . . movable frame
125 . . . annular-shaped body
126a to 126h . . . compartment region
130 . . . actuator piezoelectric element
140 . . . deflection angle sensor.

1. A MEMS optical deflector comprising:
a mirror portion configured to reflect a light beam;
a one-side torsion bar and the other-side torsion bar extending from one end portion and the other end portion of the mirror portion along a rotation axis of the mirror portion, respectively;
a one-side support and the other-side support configured to intersect the one-side torsion bar and the other-side torsion bar in a one-side intersection portion and the other-side intersection portion in a vertical direction with respect to the rotation axis, respectively, and rotatably support the one-side torsion bar and the other-side torsion bar around the rotation axis in the one-side intersection portion and the other-side intersection portion, respectively;
actuators configured to rotate the one-side torsion bar and the other-side torsion bar around the rotation axis in the one-side intersection portion and the other-side intersection portion, respectively; and
a rigidity changing piezoelectric element formed in at least one setting region of a one-side setting region and the other-side setting region including at least a part of the one-side intersection portion and the other-side intersection portion in the vertical direction in the one-side torsion bar and the other-side torsion bar in a center range, respectively to change a rigidity of the one setting region when a voltage is applied.

2. The MEMS optical deflector according to claim 1, wherein
each of the one-side setting region and the other-side setting region is set as a region including the center range and both end ranges on both sides of the center range in the vertical direction, and
the rigidity changing piezoelectric element is formed in at least one of the center range and the both end ranges.

3. The MEMS optical deflector according to claim 2, wherein
the rigidity changing piezoelectric element includes a first rigidity changing piezoelectric element formed in the center range and a second rigidity changing piezoelectric element formed in the both end ranges, and
a rigidity of the one setting region is different between when the voltage is applied only to the first rigidity changing piezoelectric element, when the voltage is applied only to the second rigidity changing piezoelectric element, and when the voltage is applied to both the first rigidity changing piezoelectric element and the second rigidity changing piezoelectric element.

4. The MEMS optical deflector according to claim 3, wherein
the other-side support has a sensor setting region on a mirror portion side or an opposite side of the mirror portion side in an extending direction of the rotation axis with respect to the both end ranges of the other-side setting region, and
a piezoelectric sensor configured to detect a rotation angle of the mirror portion around the rotation axis is formed in the sensor setting region.

5. The MEMS optical deflector according to claim 1, wherein
the one-side support and the other-side support form one annular-shaped body that surrounds the mirror portion from an outside, and
the actuators are piezoelectric actuators formed in the annular-shaped body.

6. The MEMS optical deflector according to claim 5, further comprising:
an annular movable frame body that surrounds the annular-shaped body from the outside,
wherein the movable frame body is coupled to and supported by each torsion bar on the rotation axis, and is coupled to and supported by the annular-shaped body on another rotation axis of the mirror portion.

7. An optical scanning device comprising:
the MEMS optical deflector according to claim 1;
a frequency detector configured to detect a reciprocating rotation frequency of the mirror portion around the rotation axis; and
a control unit configured to control the applied voltage of the rigidity changing piezoelectric element based on an output of the frequency detector.

8. The optical scanning device according to claim 7, wherein
the MEMS optical deflector includes a first MEMS optical deflector and a second MEMS optical deflector in which scanning regions of a light beam overlap each other in a one-side end region, and
the control unit compares resonance frequencies of the mirror portion around the rotation axis when no voltage is applied to the rigidity changing piezoelectric elements of the first MEMS optical deflector and the second MEMS optical deflector, and controls the application of the voltage of the rigidity changing piezoelectric element of the MEMS optical deflector with a lower resonance frequency such that a resonance frequency of the MEMS optical deflector with a lower resonance frequency matches a resonance frequency of the MEMS optical deflector with a higher resonance frequency.
